(19) United States
(12) Patent Application Publication
(10) Pub. No.: US 2019/0326248 A1
(43) Pub. Date: Oct. 24, 2019

(54) SEMICONDUCTOR DEVICE AND DRIVE CIRCUIT

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Masahiko HORI, Yokohama Kanagawa (JP); Hiroshi SHIBATA, Himeji Hyogo (JP); Tsutomu SANO, Yokohama Kanagawa (JP); Kazuya MARUYAMA, HigashikurumeTokyo (JP)

(21) Appl. No.: 16/289,359

(22) Filed: Feb. 28, 2019

(30) Foreign Application Priority Data
Apr. 24, 2018 (JP) 2018-083501

(51) Int. Cl. H01L 23/00

(52) U.S. Cl. CPC H01L 24/49; H01L 2224/49111; H01L 24/48; H01L 2224/45147; H01L 2224/4801; H01L 2224/48091; H01L 2224/48175; H01L 2224/48132; H01L 2224/48465; H01L 2224/48472; H01L 2924/13055; H01L 2924/13091; H01L 2224/49176; H01L 2224/49431; H01L 24/45

(57) ABSTRACT

A semiconductor device of an embodiment includes a substrate including a semiconductor element, a first electrode on the substrate and electrically connected to the semiconductor element, a second electrode on the substrate and electrically connected to the semiconductor element, and a terminal spaced from the first electrode, the substrate, and the second electrode. A first bonding wire has a first bonding portion bonded to the second electrode at a first end and a second bonding portion bonded to the terminal at a second end. A second bonding wire has a third bonding portion bonded to the second electrode at a first end and a fourth bonding portion bonded to the terminal at a second end. Each of the first and second bonding wires comprise copper and have a diameter less than or equal to 100 μm.

### CROSS-REFERENCE TO RELATED APPLICATION

This application is based upon and claims the benefit of priority from Japanese Patent Application No. 2018-083501, filed Apr. 24, 2018, the entire contents of which are incorporated herein by reference.

### FIELD

Embodiments described herein relate generally to a semiconductor device and a drive circuit.

### BACKGROUND

A power semiconductor device, which typically comprises a metal oxide semiconductor field effect transistor (MOSFET) or an insulated gate bipolar transistor (IGBT), is designed for electric power control in many fields, such as power generation and power transmission, a rotary machines such as a pump or a blower including an electric motor, power supply devices in a communication system or a factory, railroad trains driven by an alternating current (AC) motor, electric cars, and household electric appliances.

For example, when a drive circuit that drives a motor or the like using a MOSFET, the MOSFET is formed in a semiconductor substrate. A source electrode of the MOSFET is formed on a semiconductor substrate in the form of a plate. Then, the source electrode and a metallic external terminal (provided outside the MOSFET) are electrically connected to each other by using a bonding wire bonded by a wire bonder. Thereby, it is possible to lead out electric power whose switching and the like are performed by the MOSFET to the outside.

Reducing on-resistance caused by a drift layer or the like of the MOSFET is important for enhancing power conversion efficiency. However, resistance of a bonding wire, an external terminal, and the like, which are provided outside the MOSFET, is connected in series with the on-resistance caused by the drift layer or the like in the drive circuit, and thereby, the power conversion efficiency is lowered. Accordingly, it is preferable to reduce the resistance caused by the bonding wire, the external terminal, and the like so as to reduce the on-resistance.

In addition, to handle a large electric power, many semiconductor elements are provided in the semiconductor substrate. These many semiconductor elements are connected in parallel with each other to a common plate-shaped source electrode. Since a film thickness of the source electrode is usually extremely thin (approximately several microns (μm)) the source electrode itself has a large resistance. Accordingly, it is preferable to lead out electric power that is subjected to control by a semiconductor element by using a member having a resistance as low as possible so as to reduce the on-resistance.

### DESCRIPTION OF THE DRAWINGS

FIG. 1 is a schematic diagram of a drive circuit according to an embodiment.

FIGS. 2A and 2B are schematic views of a first semiconductor device according to the embodiment.

FIGS. 3A and 3B are schematic views of a second semiconductor device according to the embodiment.

FIGS. 4A and 4B are schematic cross-sectional views of the first semiconductor element according to the embodiment.

FIGS. 5A and 5B are schematic cross-sectional views of the second semiconductor element according to the embodiment.

### DETAILED DESCRIPTION

Embodiments provide a semiconductor device and a drive circuit in which on-resistance is reduced.

In general, according to one embodiment, a semiconductor device, includes a semiconductor substrate including a semiconductor element, a first electrode on a first side of the semiconductor substrate and electrically connected to the semiconductor element, a second electrode on a second side of the semiconductor substrate and electrically connected to the semiconductor element, and a terminal spaced from the first electrode, the semiconductor substrate, and the second electrode. A first bonding wire is provided having a first end, a second end, a first bonding portion bonded to the second electrode at the first end, and a second bonding portion bonded to the terminal at the second end. The first bonding wire comprises copper and has a diameter less than or equal to 100 μm. A second bonding wire is provided having a first end, a second end, a third bonding portion bonded to the second electrode at the first end, and a fourth bonding portion bonded to the terminal at the second end. The second bonding wire comprises copper and has a diameter less than or equal to 100 μm.

Hereinafter, an example embodiment will be described with reference to the drawings. In the drawings, the same reference numerals or symbols are used for the same or substantially similar aspects.

In the specification, the same or substantially similar elements or aspects are denoted by the same reference numerals or symbols, and repeated description of these elements or aspects may be omitted in some cases.

In the present specification, in order to indicate a positional relation between components or the like, an upward direction in the drawings is described as “upper” and a downward direction in the drawings is described as “lower”. Thus, in this specification, terms of “upper” and “lower” are not necessarily indicating a relationship with respect to a direction of gravity.

In the present specification, notations of n⁺, n, n⁻, p⁺, p, p⁻ represent relative impurity concentrations in each conductivity type. That is, n⁺ indicates that impurity concentration of n-type impurities/dopants is higher than impurity concentration of n, and n⁻ indicates that impurity concentration thereof is lower than impurity concentration of n. In addition, p⁺ indicates that impurity concentration of p-type impurities/dopants is higher than impurity concentration of p, and p⁻ indicates that impurity concentration thereof is lower than impurity concentration of p. In some contexts, a n⁺ and n⁻ concentration region may be described merely as an n type region, and p⁺ and p⁻ concentration region may be described merely as p type region.

In the following description of certain examples, a first conductivity type is set as n type and a second conductivity type is set as p type. However, in general, in other examples, the first conductivity type can be p type and the second conductivity type can be n type by switching the corresponding impurity type.

### Example Embodiment

A semiconductor device according to an embodiment includes a first electrode; a semiconductor substrate that is provided on the first electrode and includes a semiconductor element which is electrically connected to the first electrode; a second electrode that is provided on the semiconductor substrate and is electrically connected to the semiconductor element; a terminal that is separated from the first electrode, the semiconductor substrate, and the second electrode; a first bonding wire that includes a first one end and a first other end, a first bonding portion which is provided in the first one end and is bonded to the second electrode, a second bonding portion which is provided in the first other end and is bonded to the terminal, contains copper, and has a diameter less than or equal to 100 μm; and a second bonding wire that includes a second one end and a second other end, a third bonding portion which is provided in the second one end and is bonded to the second electrode, a fourth bonding portion which is provided in the second other end and is bonded to the terminal, contains copper, and has a diameter less than or equal to 100 μm.

In addition, a drive circuit according to the embodiment includes a first semiconductor device including a first electrode, a first semiconductor substrate that is provided on the first electrode and includes a first semiconductor element which includes a first control electrode and is electrically connected to the first electrode, a second electrode that is provided on the first semiconductor substrate and is electrically connected to the first semiconductor element, a first terminal that is separated from the first electrode, the first semiconductor substrate, and the second electrode, a first bonding wire that includes a first one end and a first other end, a first bonding portion which is provided in the first one end and is bonded to the second electrode, a second bonding portion which is provided in the first other end and is bonded to the first terminal, contains copper, and has a diameter less than or equal to 100 μm, and a second bonding wire that includes a second one end and a second other end, a third bonding portion which is provided in the second one end and is bonded to the second electrode, a fourth bonding portion which is provided in the second other end and is bonded to the first terminal, contains copper, and has a diameter less than or equal to 100 μm; a second semiconductor device including a third electrode that is electrically connected to the second electrode, a second semiconductor substrate that is provided on the third electrode and includes a second semiconductor element which includes a second control electrode and is electrically connected to the third electrode, a fourth electrode that is provided on the second semiconductor substrate and is electrically connected to the second semiconductor element, a second terminal that is separated from the third electrode, the second semiconductor substrate, and the fourth electrode, a third bonding wire that includes a third one end and a third other end, a fifth bonding portion which is provided in the third one end and is bonded to the fourth electrode, a sixth bonding portion which is provided in the third other end and is bonded to the second terminal, contains copper, and has a diameter less than or equal to 100 μm, a fourth bonding wire that includes a fourth one end and a fourth other end, a seventh bonding portion which is provided in the fourth one end and is bonded to the fourth electrode, an eighth bonding portion which is provided in the fourth other end and is bonded to the second terminal, contains copper, and has a diameter less than or equal to 100 μm; and a control element that is connected to the first control electrode and the second control electrode.

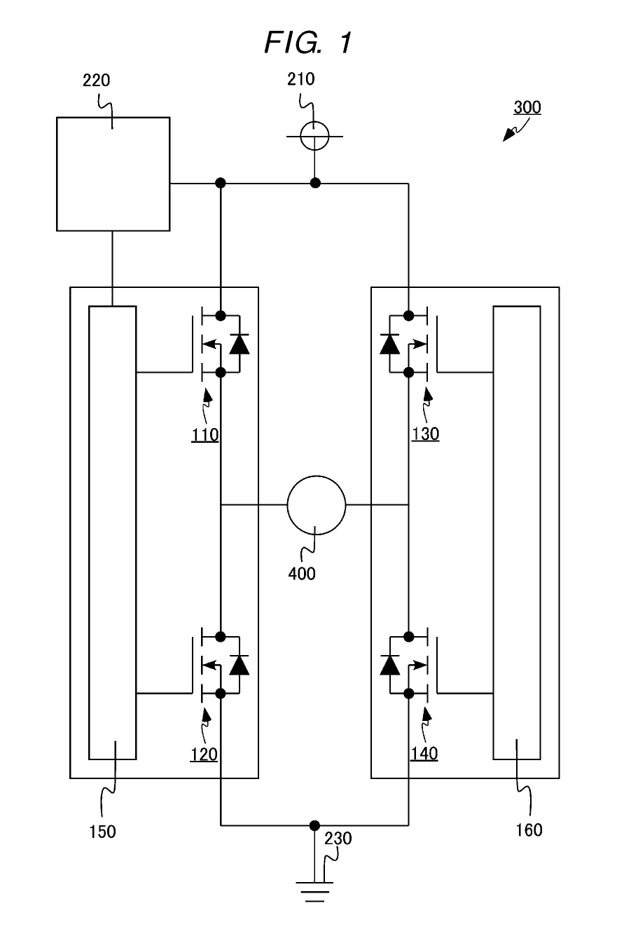

FIG. 1 is a schematic diagram of a drive circuit 300 according to an embodiment. The drive circuit 300 is a half bridge circuit for driving a rotary electric machine 400. The rotary electric machine 400 is, for example, a DC motor or a machine including a DC motor.

A first semiconductor device 110, a second semiconductor device 120, a third semiconductor device 130, and a fourth semiconductor device 140 are all n-type and normally-off-type MOSFETs. In some other examples, the first semiconductor device 110 and the third semiconductor device 130 may be p-type MOSFETs, and the second semiconductor device 120 and the fourth semiconductor device 140 may be n-type MOSFETs.

The first semiconductor device 110, the second semiconductor device 120, the third semiconductor device 130, and the fourth semiconductor device 140 may be other types of transistors besides MOSFETs, for example, an IGBT, a bipolar junction transistor (BJT), or the like. In addition, in each of the first semiconductor device 110, the second semiconductor device 120, the third semiconductor device 130, and the fourth semiconductor device 140, as illustrated in FIG. 1, a reflux diode may be connected between a source electrode and a drain electrode.

The first semiconductor device 110, the second semiconductor device 120, the third semiconductor device 130, and the fourth semiconductor device 140 comprise, for example, silicon (Si) or silicon carbide (SiC), and may be manufactured in Si or SiC substrates, for example. The first semiconductor device 110, the second semiconductor device 120, the third semiconductor device 130, and the fourth semiconductor device 140 may also be manufactured by using a nitride semiconductor material such as GaN (gallium nitride), AlGaN or InGaN, gallium oxide (GaO), or a diamond-based semiconductor.

A first power supply 210 is, for example, a DC power supply that supplies a positive voltage. The first power supply 210 is electrically connected to a drain electrode of the first semiconductor device 110 and a drain electrode of the third semiconductor device 130. A source electrode of the first semiconductor device 110 is electrically connected to a drain electrode of the second semiconductor device 120. A source electrode of the third semiconductor device 130 is electrically connected to a drain electrode of the fourth semiconductor device 140. A source electrode of the second semiconductor device 120 and a source electrode of the fourth semiconductor device 140 are electrically connected to a ground 230. Thus, the first semiconductor device 110 and the second semiconductor device 120 and the third semiconductor device 130 and the fourth semiconductor device 140 are connected in parallel between the first power supply 210 and the ground 230.

The rotary electric machine 400 is electrically connected between the source electrode of the first semiconductor device 110 and the drain electrode of the second semiconductor device 120 on one side, and the source electrode of the third semiconductor device 130 and the drain electrode of the fourth semiconductor device 140 on the other side.

A first control element 150 is connected to a gate electrode of the first semiconductor device 110 and a gate electrode of the second semiconductor device 120. The first control element 150 controls, for example, a variable resistance or variable resistor (not specifically depicted) between the gate electrode of the first semiconductor device 110 and the first control element 150, and a variable resistance or variable resistor (not specifically depicted) between the gate electrode of the second semiconductor device 120 and the first control element 150 to perform switching of the first semiconductor device 110 and the second semiconductor device 120.

A second control element 160 is connected to a gate electrode of the third semiconductor device 130 and a gate electrode of the fourth semiconductor device 140. The second control element 160 controls, for example, a variable resistance or variable resistor (not specifically depicted) between the gate electrode of the third semiconductor device 130 and the second control element 160 and a variable resistance or variable resistor (not specifically depicted) between the gate electrode of the fourth semiconductor device 140 and the second control element 160 to perform switching of the third semiconductor device 130 and the fourth semiconductor device 140.

The first control element 150 and the second control element 160 are, for example, integrated circuits or electronic circuits provided in a semiconductor chip. The first control element 150 and the second control element 160 are, for example, computers implemented by a combination of hardware, such as an arithmetic circuit, and software, such as a program. The first control element 150 and the second control element 160 may be implemented as hardware, such as an electric circuit, a quantum circuit, or the like, or may be a processor configured with software executing thereon. When configured with software, the processor in such a case may be a microprocessor comprising a central processing unit (CPU), a read only memory (ROM) for storing a processing program, a random access memory (RAM) for temporarily storing data, input and output ports, and a communication port. A recording medium is not limited to a detachable device such as a magnetic disk or an optical disk, but may be a fixed type recording medium such as a hard disk device or a semiconductor memory.

A second power supply 220 is, for example, a commercially available power supply. The second power supply 220 supplies power for driving the first control element 150 and the second control element 160.

As one drive mode of the rotary electric machine 400 by the drive circuit 300, the first control element 150 and the second control element 160 are used to turn on the first semiconductor device 110 and the fourth semiconductor device 140 and to turn off the second semiconductor device 120 and the third semiconductor device 130. Thereby, a current supplied from the first power supply 210 flows from the first semiconductor device 110 to the rotary electric machine 400 and flows into the ground 230 via the fourth semiconductor device 140. Thereby, the rotary electric machine 400 rotates in a first direction, for example, in a forward direction.

In addition, as another drive mode of the rotary electric machine 400 by the drive circuit 300, the first control element 150 and the second control element 160 are used to turn off the first semiconductor device 110 and the fourth semiconductor device 140 and to turn on the second semiconductor device 120 and the third semiconductor device 130. Thereby, a current supplied from the first power supply 210 flows from the third semiconductor device 130 to the rotary electric machine 400 and flows to the ground 230 via the second semiconductor device 120. Thereby, the rotary electric machine 400 rotates in a second direction, for example, in a reverse direction. As described above, it is possible to rotate the rotary electric machine 400 in either the forward direction or the reverse direction by using the drive circuit 300.

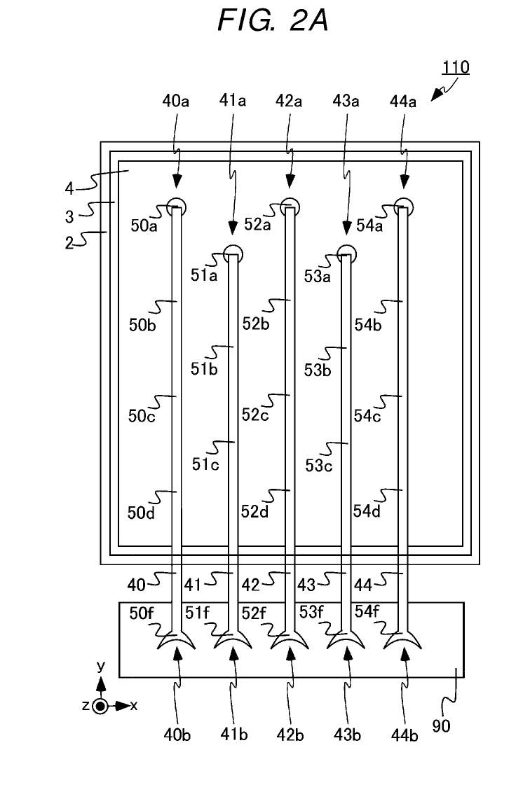

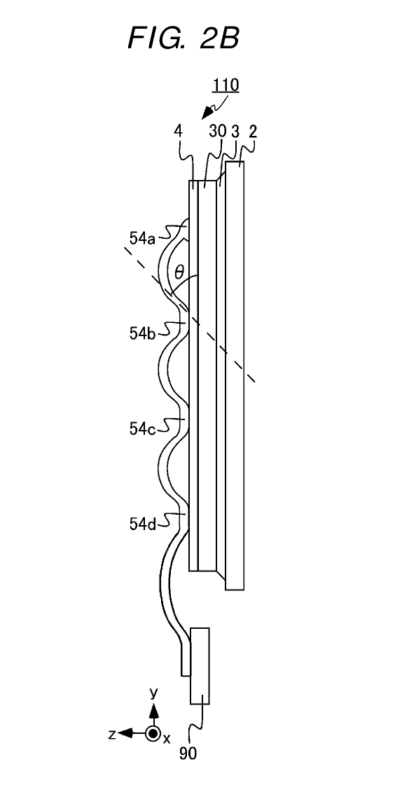

FIGS. 2A and 2B are schematic diagrams of the first semiconductor device 110. The first semiconductor device 110 is an example of a semiconductor device.

Here, an x direction, a y direction perpendicular to the x direction, and a z direction perpendicular to the x direction and the y direction are defined for purposes of explanation in FIGS. 2A and 2B. FIG. 2A is a schematic view of the first semiconductor device 110 when viewed from the z direction. FIG. 2B is a schematic view of the first semiconductor device 110 when viewed from the x direction. In FIG. 2B, the separate depiction bonding wires 40, 41, 42, 43, and 44 is omitted. In addition, the first semiconductor device 110 illustrated in FIGS. 2A and 2B is sealed/packaged within, for example, a resin or the like.

The first semiconductor substrate 30 is, for example, a silicon (Si) substrate or a silicon-carbide (SiC) substrate. The first semiconductor substrate 30 may also be a nitride semiconductor substrate, a GaO substrate, or a diamond semiconductor substrate. The first semiconductor substrate 30 is disposed such that a substrate surface thereof is parallel to an xy plane. The first semiconductor substrate 30 is an example of a semiconductor substrate.

A first drain electrode 2 is provided under the first semiconductor substrate 30 so as to be in contact with a lower substrate surface of the first semiconductor substrate 30. In other words, the first semiconductor substrate 30 is provided on the first drain electrode 2. The first drain electrode 2 comprises, for example, copper, silver, or gold and has a plate-like shape or a thin-film shape disposed in parallel to the xy plane. In the first semiconductor device 110, the first semiconductor substrate 30 is fixed/attached onto the first drain electrode 2 by using a conductive paste 3 of a known type. The first drain electrode 2 is an example of a first electrode.

A first source electrode 4 is provided on the first semiconductor substrate 30 so as to be in contact with an upper substrate surface of the first semiconductor substrate 30. The first source electrode 4 comprises, for example, copper, silver, or gold and has a plate-like shape or a thin-film shape disposed in parallel to the xy plane. The first source electrode 4 is an example of a second electrode.

The first terminal 90 is separated from the first drain electrode 2, the first semiconductor substrate 30, and the first source electrode 4 in the y direction. The first terminal 90 is formed of, for example, copper. The first terminal 90 is an example of a terminal.

The bonding wire 40 has one end 40a and the other end 40b. A bonding portion 50a is provided at the one end 40a and is bonded to the first source electrode 4. A bonding portion 50f is provided at the other end 40b and is bonded to the first terminal 90. In addition, the bonding wire 40 is bonded to the first source electrode 4 at bonding portions 50b, 50c, and 50d between the one end 40a and the other end 40b. The bonding wire 40 is an example of a first bonding wire. The one end 40a and the other end 40b are examples of a first one end and a first other end.

The bonding portion 50a is a bump, for example. In this context, formation of bonding wire 40 including a bonding portion 50a can be performed by passing a boding wire through the tip of a capillary of a wire bonder and is attached to an electrode which is the bonding target. A part of the bonding wire is melted by heating the tip of the bonding wire, and thereby, a ball portion is formed. In this state, the ball portion is pressed against the electrode using a tip end portion of the capillary, and if a load or an ultrasonic vibration is applied, a bump is formed on the electrode. The bonding portion 50a is an example of a first bonding portion.

The bonding portions 50b, 50c, 50d, and 50f are stitches. A stitch is formed by the bonding wire being pressed onto the electrode by the capillary tip, without the capillary tip being heated, and applying weight or ultrasonic vibration. A diameter of the bonding wire in the portions of the bonding portions 50b, 50c, 50d, and 50f may be approximately ½ to ⅓ of an original diameter of the bonding wire when pressed onto the electrode. After the bonding portion 50f is formed, the bonding wire 40 is cut by using a cutting tool provided in the wire bonder. The bonding portion 50f is an example of a second bonding portion. In addition, the bonding portion 50b is an example of a fifth bonding portion or a ninth bonding portion.

The bonding wire 41 has one end 41a and the other end 41b. A bonding portion 51a is provided at the one end 41a and is bonded to the first source electrode 4. A bonding portion 51f is provided at the other end 41b and is bonded to the first terminal 90. In addition, the bonding wire 41 is bonded to the first source electrode 4 at the bonding portions 51b and 51c between the one end 41a and the other end 41b. The bonding wire 41 is an example of a second bonding wire. The one end 41a and the other end 41b are examples of a second one end and a second other end.

The bonding portion 51a is a bump. The bonding portions 51b, 51c, and 51f are stitches. The bonding portion 51a is an example of a third bonding portion. In addition, the bonding portion 51f is an example of a fourth bonding portion.

The bonding wire 42 has one end 42a and the other end 42b. A bonding portion 52a is provided at the one end 42a and is bonded to the first source electrode 4. A bonding portion 52f is provided at the other end 42b and is bonded to the first terminal 90. In addition, the bonding wire 42 is bonded to the first source electrode 4 at bonding portions 52b, 52c, and 52d between the one end 42a and the other end 42b.

The bonding portion 52a is a bump. The bonding portions 52b, 52c, 52d, and 52f are stitches.

The bonding wire 43 has one end 43a and the other end 43b. A bonding portion 53a is provided at the one end 43a and is bonded to the first source electrode 4. A bonding portion 53f is provided at the other end 43b and is bonded to the first terminal 90. In addition, the bonding wire 43 is bonded to the first source electrode 4 at bonding portions 53b and 53c between the one end 42a and the other end 42b.

The bonding portion 53a is a bump. The bonding portions 53b, 53c, and 53f are stitches.

The bonding wire 44 has one end 44a and the other end 44b. A bonding portion 54a is provided at the one end 44a and is bonded to the first source electrode 4. A bonding portion 54f is provided at the other end 44b and is bonded to the first terminal 90. In addition, the bonding wire 44 is bonded to the first source electrode 4 at bonding portions 54b, 54c, and 54d between the one end 44a and the other end 44b.

The bonding portion 54a is a bump. The bonding portions 54b, 54c, 54d, and 54f are stitches.

All the bonding wires 40, 41, 42, 43, and 44 comprise copper and are, for example, copper bonding wires having diameters less than or equal to 100 μm. A copper bonding wire coated with another material such as palladium (Pd) may also be used as the bonding wires 40, 41, 42, 43, and 44.

In the plane parallel to the substrate surface of the first semiconductor substrate 30, distances between adjacent bonding portions among the bonding portions formed on the first source electrode 4 are equal to each other. For example, taking the bonding portions 50a, 50b, 50c, and 50d of the bonding wire 40 and the bonding portions 51a, 51b, and 51c of the bonding wire 41 as an example, a distance between the bonding portion 50a and the bonding portion 50b, a distance between the bonding portion 50b and the bonding portion 50c, a distance between the bonding portion 50c and the bonding portion 50d, a distance between the bonding portion 50a and the bonding portion 51a, a distance between the bonding portion 51a and the bonding portion 50b, a distance between the bonding portion 51a and the bonding portion 51b, a distance between the bonding portion 51b and the bonding portion 51c, a distance between the bonding portion 50b and the bonding portion 51b, a distance between the bonding portion 51b and the bonding portion 50c, a distance between the bonding portion 50c and the bonding portion 51c, and a distance between the bonding portion 51c and the bonding portion 50d are all substantially equal to each other. Here, the distance between the bonding portions is, for example, a distance between the central portions of the respective bonding portions. It is preferable to measure a distance between the projected portions after projecting the central portions of the respective bonding portions onto the substrate surface such that the distance is accurately measured. In addition, due to problems with the accuracy of movement of a capillary of a wire bonder in the xy plane, a deviation of approximately 5% may occur in the intended spacing distance, but even if such a deviation occurs, it is assumed that the resulting distances are “equal” to each other for purposes of the present specification.

In addition, among the bonding portions formed on the first source electrode 4, the distance between adjacent bonding portions is preferably greater than or equal to 200 μm and less than or equal to 1000 μm.

The bonding wires 40, 41, 42, 43, and 44 are all bonded in a state of extending in they direction. Accordingly, for example, if a portion between the bonding portions 50a and 50d of the bonding wire 40, a portion between the bonding portions 51a and 51c of the bonding wire 41, a portion between the bonding portions 52a and 52d of the bonding wire 42, a portion between the bonding portions 53a and 53c of the bonding wire 43, and a portion between the bonding portions 54a and 54d of the bonding wire 44 are projected onto the substrate surface of the first semiconductor substrate 30, all the portions are parallel to each other and are parallel to the y direction.

If an angle θ between a surface of the first source electrode 4 and the bonding wire illustrated in FIG. 2B is too large, the bonding wire will be easily peeled off from the first source electrode 4 and the bonding wire will be easily broken. The angle θ between the surface of the first source electrode 4 and the bonding wires is preferably less than or equal to 20 degrees and is more preferably less than or equal to 15 degrees.

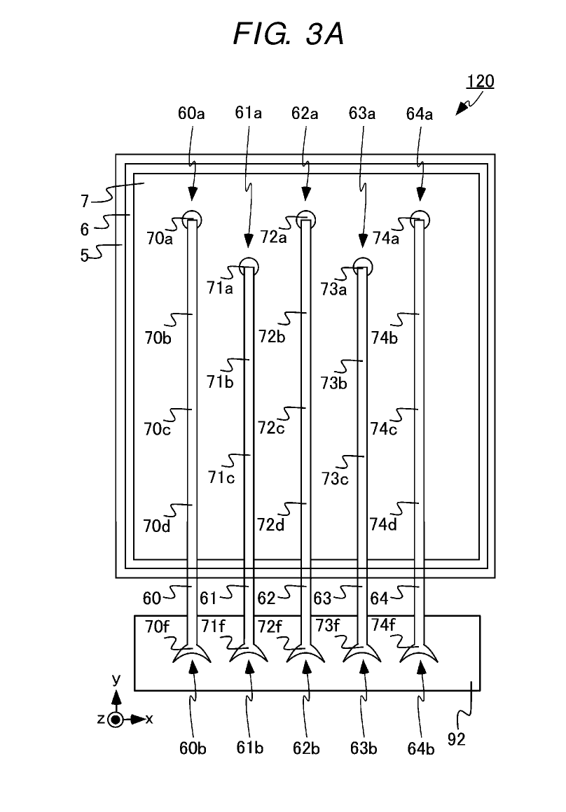

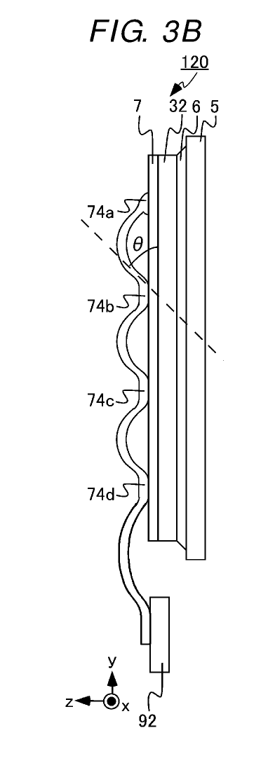

FIGS. 3A and 3B are schematic views of the second semiconductor device 120 according to an embodiment. Descriptions of the same points in the first semiconductor device 110 illustrated in FIGS. 2A and 2B will be omitted.

A second drain electrode 5 is provided under a second semiconductor substrate 32 and is in contact with a lower substrate surface of the second semiconductor substrate 32. In other words, the second semiconductor substrate 32 is provided on the first drain electrode 2. In the second semiconductor device 120 according to the embodiment, the second semiconductor substrate 32 is fixed/attached onto the second drain electrode 5 by using a conductive paste 6, which may the same or different type of paste as conductive paste 3. The second drain electrode 5 is an example of a third electrode.

A second source electrode 7 is provided on the second semiconductor substrate 32 so as to be in contact with an upper substrate surface of the second semiconductor substrate 32. The second source electrode 7 is an example of a fourth electrode.

A second terminal 92 is separated from the second drain electrode 5, the second semiconductor substrate 32, and the second source electrode 7 in the y direction. The second terminal 92 is formed of, for example, copper.

A bonding wire 60 has one end 60a and the other end 60b. A bonding portion 70a is provided at one end 60a and is bonded to the second source electrode 7. A bonding portion 70f is provided at the other end 60b and is bonded to the second terminal 92. In addition, the bonding wire 60 is bonded to the second source electrode 7 at bonding portions 70b, 70c, and 70d between the one end 60a and the other end 60b. The bonding wire 60 is an example of a third bonding wire. The one end 60a and the other end 60b are examples of a third one end and a third other end.

The bonding portion 70a is a bump. The bonding portions 70b, 70c, 70d, and 70f are stitches. The bonding portion 70a is an example of a fifth bonding portion. In addition, the bonding portion 70f is an example of a sixth bonding portion. In addition, the bonding portion 70b is an example of a tenth bonding portion.

A bonding wire 61 has one end 61a and the other end 61b. A bonding portion 71a is provided at the one end 61a and is bonded to the second source electrode 7. A bonding portion 71f is provided at the other end 61b and is bonded to the second terminal 92. In addition, the bonding wire 61 is bonded to the second source electrode 7 at bonding portions 71b and 71c between the one end 61a and the other end 61b. The bonding wire 61 is an example of a fourth bonding wire. The one end 61a and the other end 61b are examples of a fourth one end and a fourth other end.

The bonding portion 71a is a bump. The bonding portions 71b, 71c, and 71f are stitches. The bonding portion 71a is an example of a seventh bonding portion. In addition, the bonding portion 71f is an example of an eighth bonding portion.

A bonding wire 62 has one end 62a and the other end 62b. A bonding portion 72a is provided at the one end 62a and is bonded to the second source electrode 7. A bonding portion 72f is provided at the other end 62b and is bonded to the second terminal 92. In addition, the bonding wire 62 is bonded to the second source electrode 7 at bonding portions 72b, 72c, and 72d between the one end 62a and the other end 62b.

The bonding portion 72a is a bump. The bonding portions 72b, 72c, 72d, and 72f are stitches.

A bonding wire 63 has one end 63a and the other end 63b. A bonding portion 73a is provided at the one end 63a and is bonded to the second source electrode 7. A bonding portion 73f is provided at the other end 63b and is bonded to the second terminal 92. In addition, the bonding wire 63 is bonded to the second source electrode 7 at bonding portions 73b and 73c between the one end 63a and the other end 63b.

The bonding portion 73a is a bump. The bonding portions 73b, 73c, and 73f are stitches.

A bonding wire 64 has one end 64a and the other end 64b. A bonding portion 74a is provided at the one end 64a and is bonded to the second source electrode 7. A bonding portion 74f is provided at the other end 64b and is bonded to the second terminal 92. The bonding wire 64 is bonded to the first source electrode 4 at bonding portions 74b, 74c, and 74d between the one end 64a and the other end 64b.

The bonding portion 74a is a bump. The bonding portions 74b, 74c, 74d, and 74f are stitches.

In a plane parallel to the substrate surface of the second semiconductor substrate 32, distances between adjacent bonding portions among the bonding portions formed on the second source electrode 7 are substantially equal to each other.

The bonding wires 60, 61, 62, 63 and 64 are all bonded in a state of extending in they direction. Accordingly, for example, a portion between the bonding portions 70a and 70d of the bonding wire 60, a portion between the bonding portions 71a and 71c of the bonding wire 61, a portion between the bonding portions 72a and 72d of the bonding wire 62, a portion between the bonding portions 73a and 73c of the bonding wire 63, and a portion between the bonding portions 74a and 74d of the bonding wire 64 are projected onto the substrate surface of the second semiconductor substrate 32, the portions are parallel to each other and are parallel to the y direction.

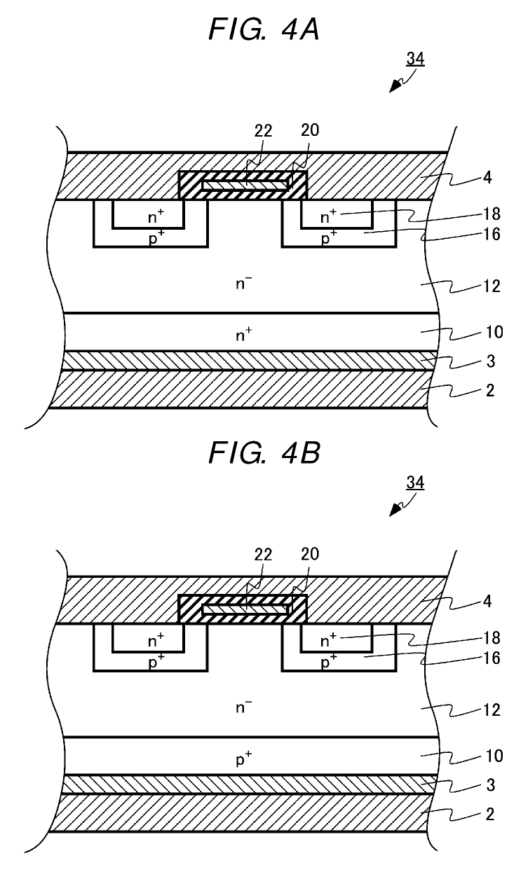

FIGS. 4A and 4B are schematic cross-sectional views of a first semiconductor element 34 according to an embodiment.

The first semiconductor element 34 illustrated in FIG. 4A is a double implanted MOSFET (DiMOSFET).

The first semiconductor element 34 includes a first collector layer 10, a first drift layer 12, a first base layer 16, a first source layer 18, a first gate insulating film 20, and a first gate electrode 22. The first semiconductor element 34.

The n⁺ type first collector layer 10 is provided in the first semiconductor substrate 30 and is electrically connected to the first drain electrode 2 via the conductive paste 3. The first collector layer 10 is an example of a first semiconductor layer.

The n⁻ type first drift layer 12 is provided on the first collector layer 10 in the first semiconductor substrate 30. The first drift layer 12 is an example of a second semiconductor layer.

The p⁻ type first base layer 16 is provided on the first drift layer 12 in the first semiconductor substrate 30. In addition, a part of the first base layer 16 is in contact with a substrate surface on the first semiconductor substrate 30. The first base layer 16 is an example of a first semiconductor region.

The n⁺ type first source layer 18 is in contact with an upper substrate surface of the first semiconductor substrate 30, between the first base layer 16 and the first source electrode 4 in the first semiconductor substrate 30. The first source layer 18 is electrically connected to the first source electrode 4. The first source layer 18 is an example of a second semiconductor region.

The first gate insulating film 20 is provided on the first drift layer 12 of the first semiconductor substrate 30. When the first semiconductor substrate 30 is a Si substrate, the first gate insulating film 20 is formed of, for example, silicon oxide.

The first gate electrode 22 is provided in the first gate insulating film 20. The first gate electrode 22 is an example of a first control electrode or a control electrode.

In the first semiconductor substrate 30, a plurality of first semiconductor elements 34 are arrayed side by side in the x direction and the y direction. The plurality of first semiconductor elements 34 are all connected in parallel between the first drain electrode 2 and the first source electrode 4. That is, the first drain electrode 2 and the first source electrode 4 are used in common by the plurality of first semiconductor elements 34.

The first semiconductor element 34 illustrated in FIG. 4B is an IGBT and is the same as the MOSFET illustrated in FIG. 4A excepting that the collector layer is a p⁺ type. Either the MOSFET illustrated in FIG. 4A or the IGBT illustrated in FIG. 4B may be suitably used as the first semiconductor element 34.

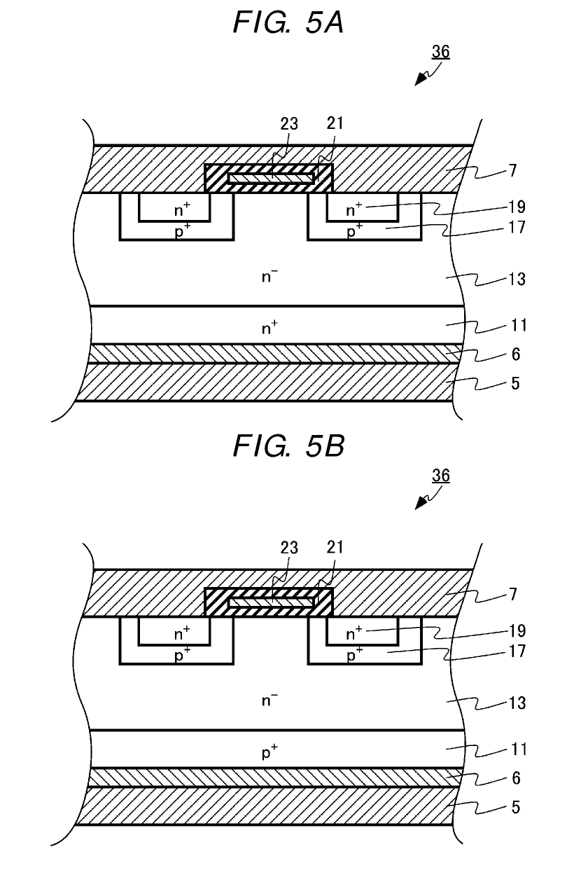

FIGS. 5A and 5B are schematic cross-sectional views of a second semiconductor element 36 according to an embodiment. The second semiconductor element 36 illustrated in FIG. 5A is a DiMOSFET. The second semiconductor element 36 illustrated in FIG. 5B is an IGBT. The second semiconductor element 36 includes a second collector layer 11, a second drift layer 13, a second base layer 17, a second source layer 19, a second gate insulating film 21, and a second gate electrode 23. The second gate electrode 23 is an example of a second control electrode.

Next, operation effects of a semiconductor device and a drive circuit according to embodiments will be described.

A film thickness of a source electrode is usually extremely thin, approximately 1 μm to 3 μm. An aluminum bonding wire is connected to a plate-shaped source electrode as an element for leading out electric power or the like which is being switched by a semiconductor element with a resistance of as low as possible via this source electrode. However, since the aluminum bonding wire itself has a high resistivity, there is a problem that power conversion efficiency is reduced.

Therefore, in order to reduce the resistance, it is conceivable to increase the number of aluminum bonding wires. However, if wire bonding is performed by changing the height of the loop of the bonding wire bonded onto the source electrode in order to increase the number of bonding wires as much as possible, a problem occurs in which the height of the entire semiconductor device increases, and the device may not be made suitably thin.

In addition, it is conceivable to use an aluminum bonding wire having a larger diameter. In this case, when wire bonding is performed, a tip end portion of a capillary will be more strongly pressed against the source electrode. Accordingly, a semiconductor element formed in the semiconductor substrate may be mechanically damaged in the wire bonding processes. In addition, such damaged semiconductor elements may cause an electrical short circuit.

It is possible to reduce the resistivity by using a ribbon style bonding instead of a standard (substantially round) bonding wire shape. However, in attempting to set ribbon bonding portions at close but equal intervals on the source electrode, a problem occurs in that a portion of another adjacent ribbon may be heated and melted.

In addition, it is conceivable, for example, to use a copper clip to bond a surface of the clip to the entire surface of a plate-shaped source electrode with solder or the like. However, when the bonding is performed by using the solder, flux (resin) in the solder spreads around the source electrode. There is a problem that the scattered flux may have to be removed because surround members/components may corrode due to the presence of the flux.

In view of the above, a bonding wire comprising copper and having a diameter less than or equal to 100 μm is used for the semiconductor device according to an embodiment. Resistivity of the bonding wire comprising copper is less than resistivity of the bonding wire comprising aluminum. Accordingly, even if a bonding wire having a diameter less than or equal to 100 μm is used, the resistivity will be less than the resistivity of the aluminum bonding wire. In addition, since the diameter is less than or equal to 100 μm, it is possible to bond the bonding wire to a source electrode without heavily pressing a tip end portion of a capillary against the source electrode. Accordingly, damage to semiconductor elements in the semiconductor substrate and generation of electrical short circuits can be prevented. Thus, it is possible to provide a semiconductor device with reduced on-resistance.

As described above, in the semiconductor substrate, a plurality of semiconductor elements are arranged side by side in the x direction and the y direction. Electric power which is switched by a semiconductor element is led out via a bonding portion closest to the semiconductor element. Thus, when there is a variation in a distance between adjacent bonding portions, there is a risk that a semiconductor element will be provided at a location at an extreme distant from a bonding portion, and a problem may occur in which power conversion efficiency is reduced.

Therefore, distances between the adjacent bonding portions among the bonding portions formed on the source electrodes are made equal to each other, and thereby, a semiconductor element provided at a location extremely far from the bonding portion is not provided. Thereby, it is possible to provide a semiconductor device with reduced on-resistance.

Since a bump forms into a ball at the tip of the bonding wire and is bonded to the source electrode, the bonding portion is highly reliable. Accordingly, by making the bonding portion at one end of the bonding wire a bump, a semiconductor device with a higher reliability can be provided.

It is preferable that the distance between adjacent bonding portions among the bonding portions formed on the source electrode is greater than or equal to 200 μm and less than or equal to 1000 μm. When the distance exceeds 1000 μm, resistance of the source electrode increases too much for a current flowing through a transistor provided at a location distant from the bonding portion and flowing into the bonding portion. When the distance is less than 200 μm, the angle θ formed between a surface of the source electrode and the bonding wire increases too much, and the bonding wire is too easily peeled or broken.

When portions between the bonding portions of each bonding wire are projected onto a substrate surface of the semiconductor substrate, the distances between adjacent bonding portions are equalized to each other by making the distances parallel to a specific direction such as the y direction. Thus, it is possible to provide a semiconductor device with further reduced on-resistance.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions, and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A semiconductor device, comprising:
a semiconductor substrate including a semiconductor element;
a first electrode on a first side of the semiconductor substrate and electrically connected to the semiconductor element;
a second electrode on a second side of the semiconductor substrate and electrically connected to the semiconductor element;
a terminal spaced from the first electrode, the semiconductor substrate, and the second electrode;
a first bonding wire having a first end, a second end, a first bonding portion bonded to the second electrode at the first end, and a second bonding portion bonded to the terminal at the second end, the first bonding wire comprising copper and having a diameter less than or equal to 100 μm; and
a second bonding wire having a first end, a second end, a third bonding portion bonded to the second electrode at the first end, and a fourth bonding portion bonded to the terminal at the second end, the second bonding wire comprising copper and having a diameter less than or equal to 100 μm.

2. The semiconductor device according to claim 1, wherein
the first bonding wire further includes a fifth bonding portion bonded to the second electrode between the first and second ends of the first bonding wire, and
a distance from the first bonding portion to the third bonding portion, a distance from the first bonding portion to the fifth bonding portion, and a distance from the third bonding portion to the fifth bonding portion are each equal to one another.

3. The semiconductor device according to claim 2, wherein the distance from the first bonding portion to the fifth bonding portion is greater than or equal to 200 μm and less than or equal to 1000 μm.

4. The semiconductor device according to claim 1, wherein
the first bonding wire further includes a fifth bonding portion bonded to the second electrode between the first and second ends of the first bonding wire,
the first bonding portion and the third bonding portion are bumps, and
the second bonding portion, the fourth bonding portion, and the fifth bonding portion are stitches.

5. The semiconductor device according to claim 4, wherein a distance from the first bonding portion to the fifth bonding portion is greater than or equal to 200 μm and less than or equal to 1000 μm.

6. The semiconductor device according to claim 4, wherein a projection of the first bonding wire onto the semiconductor substrate is parallel to a projection of the second bonding wire onto the semiconductor substrate.

7. The semiconductor device according to claim 4, wherein the first bonding wire the second bonding wire are substantially parallel to each other along a direction from the semiconductor substrate to the terminal.

8. The semiconductor device according to claim 1, wherein the semiconductor element is a transistor.

9. The semiconductor device according to claim 1, wherein the semiconductor element comprises:
a first semiconductor layer on the first electrode and electrically connected to the first electrode;
a second semiconductor layer of a first conductivity type on the first semiconductor layer;
a first semiconductor region of a second conductivity type on the second semiconductor layer;
a second semiconductor region of the first conductivity type between the first semiconductor region and a second electrode, the second semiconductor region being electrically connected to the second electrode;
an insulating film on the second semiconductor layer; and
a control electrode on the insulating film.

10. The semiconductor device according to claim 9, wherein the first semiconductor layer is the first conductivity type.

11. The semiconductor device according to claim 9, wherein the first semiconductor layer is the second conductivity type.

12. The semiconductor device according to claim 1, wherein
the first bonding portion comprises a bump connection, and
the third bonding portion comprises a bump connection.

13. The semiconductor device according to claim 12, wherein the first bonding wire is stitch-connected to the second electrode at a plurality of locations between the first and second ends of the first bonding wire.

14. The semiconductor device according to claim 13, wherein
the second bonding wire is stitch-connected to the second electrode at a plurality of locations between the first and second ends of the second bonding wire, and
the plurality of locations between the first and second ends of the first bonding wire are offset from the plurality of locations between the first and second ends of the second bonding wire in a direction from the second electrode to the terminal.

15. A drive circuit, comprising:
a first semiconductor device including:
a first semiconductor substrate including a first semiconductor element having a first control electrode;
a first electrode on a first side of the first semiconductor substrate and electrically connected to the first semiconductor element;
a second electrode on a second side of the first semiconductor substrate and electrically connected to the first semiconductor element;
a first terminal spaced from the first electrode, the first semiconductor substrate, and the second electrode;
a first bonding wire having a first end, a second end, a first bonding portion bonded to the second electrode at the first end, and a second bonding portion bonded to the first terminal at the second end, the first bonding wire comprising copper and having a diameter less than or equal to 100 μm; and
a second bonding wire having a first end, a second end, a third bonding portion bonded to the second electrode at the first end, and a fourth bonding portion bonded to the first terminal at the second end, the second bonding wire comprising copper and having a diameter less than or equal to 100 μm;
a second semiconductor device including:
a second semiconductor substrate including a second semiconductor element having a second control electrode;
a third electrode on a first side of the second semiconductor substrate and electrically connected to the second semiconductor element;
a fourth electrode on a second side of the second semiconductor substrate and electrically connected to the second semiconductor element;
a second terminal spaced from the third electrode, the second semiconductor substrate, and the fourth electrode;
a third bonding wire having a first end, a second end, a first bonding portion bonded to the fourth electrode at the first end, and a second bonding portion bonded to the second terminal at the second end, the third bonding wire comprising copper and having a diameter less than or equal to 100 μm; and
a fourth bonding wire having a first end, a second end, a third bonding portion bonded to the fourth electrode at the first end, and a fourth bonding portion bonded to the second terminal at the second end, the fourth bonding wire comprising copper and having a diameter less than or equal to 100 μm; and
a controller element connected to the first control electrode and the second control electrode.

16. The drive circuit according to claim 15, wherein the first semiconductor element is an insulated gate bipolar transistor.

17. The drive circuit according to claim 15, wherein the first semiconductor device and the second semiconductor device are connected to an electric motor.

18. A drive circuit, comprising:
a first and second semiconductor device connected in series between a first power supply terminal and a ground terminal and configured to supply power to a load terminal, wherein each of the first and second semiconductor devices respectively comprises:
a semiconductor substrate including a transistor;
a first electrode on a first side of the semiconductor substrate and electrically connected to the transistor;
a second electrode on a second side of the semiconductor substrate and electrically connected to the transistor;
a terminal spaced from the first electrode, the semiconductor substrate, and the second electrode;
a first bonding wire having a first end, a second end, a first bonding portion bonded to the second electrode at the first end, and a second bonding portion bonded to the terminal at the second end, the first bonding wire comprising copper and having a diameter less than or equal to 100 μm; and
a second bonding wire having a first end, a second end, a third bonding portion bonded to the second electrode at the first end, and a fourth bonding portion bonded to the terminal at the second end, the second bonding wire comprising copper and having a diameter less than or equal to 100 μm.

19. The drive circuit according to claim 18, wherein
the first bonding wire of each of the first and second semiconductor devices further includes a fifth bonding portion bonded to the second electrode between the first and second ends of the first bonding wire,
the first bonding portion and the third bonding portion of each of the first and second semiconductor devices are bumps, and
the second bonding portion, the fourth bonding portion, and the fifth bonding portion of each of the first and second semiconductor devices are stitches.

20. The drive circuit according to claim 18, wherein
the first bonding portion of each of the first and second semiconductor devices comprises a bump connection,
the third bonding portion of each of the first and second semiconductor devices comprises a bump connection, and
the first bonding wire of each of the first and second semiconductor devices is stitch-connected to the respective second electrode of the first and second semiconductor devices at a plurality of locations between the first and second ends of the first bonding wire.
